(19) United States
(12) Patent Application Publication
(10) Pub. No.: US 2023/0090469 A1
(43) Pub. Date: Mar. 23, 2023

(54) LIGHT-EMITTING DEVICE AND METHOD OF MANUFACTURING LIGHT-EMITTING DEVICE

(71) Applicant: SONY SEMICONDUCTOR SOLUTIONS CORPORATION, KANAGAWA (JP)

(72) Inventor: TAKAHIRO ARAKIDA, KUMAMOTO (JP)

(21) Appl. No.: 17/904,073

(22) PCT Filed: Feb. 4, 2021
(86) PCT No.: PCT/JP2021/004102

§ 371 Date: Aug. 11, 2022

(30) Foreign Application Priority Data
Feb. 18, 2020 (JP) 2020-025190

(51) Int. Cl. H01S 5/183; H01S 5/42

(52) U.S. Cl. CPC H01S 5/18361; H01S 5/18305; H01S 5/423; H01S 2301/173; H01S 5/18311; H01S 5/34313

(57) ABSTRACT

A light-emitting device according to an embodiment of the present disclosure includes: a semiconductor stack in which a first light reflection layer configured by an arsenic-based semiconductor layer including carbon as an impurity, an active layer, and a second light reflection layer are stacked; a first buffer layer provided on the first light reflection layer side of the semiconductor stack, having one face that faces the semiconductor stack and another face that is on an opposite side of the one face, and configured by a phosphorus-based semiconductor layer; and a second buffer layer provided at least between the first light reflection layer and the first buffer layer, and configured by an arsenic-based semiconductor layer including zinc or magnesium as an impurity.

### TECHNICAL FIELD

The present disclosure relates to a light-emitting device and a method of manufacturing a light-emitting device.

### BACKGROUND ART

For example, Patent Literature 1 discloses a surface light-emission laser that stabilizes laser oscillation by providing, on DBR in which carbon (C) is doped as an impurity, a protection layer configured by p-type InGaP in which zinc (Zn) is doped as an impurity.

### CITATION LIST

### Patent Literature

Patent Literature 1: Japanese Unexamined Patent Application Publication No. 2000-164982

### SUMMARY OF THE INVENTION

Incidentally, for a light-emitting device, it is desired to improve stability of a device characteristic and a manufacturing yield.

It is desirable to provide a light-emitting device and a method of manufacturing a light-emitting device that make it possible to improve stability of a device characteristic and a manufacturing yield.

A light-emitting device according to one embodiment of the present disclosure includes: a semiconductor stack in which a first light reflection layer configured by an arsenic-based semiconductor layer including carbon as an impurity, an active layer, and a second light reflection layer are stacked; a first buffer layer provided on the first light reflection layer side of the semiconductor stack, having one face that faces the semiconductor stack and another face that is on an opposite side of the one face, and configured by a phosphorus-based semiconductor layer; and a second buffer layer provided at least between the first light reflection layer and the first buffer layer, and configured by an arsenic-based semiconductor layer including zinc or magnesium as an impurity.

A method of manufacturing a first light-emitting device according to one embodiment of the present disclosure includes: forming a first buffer layer configured by a phosphorus-based semiconductor layer, a second buffer layer configured by an arsenic-based semiconductor layer including zinc or magnesium as an impurity, a first light reflection layer configured by an arsenic-based semiconductor layer including carbon as an impurity, an active layer, and a second light reflection layer in this order by a crystal growth; and thereafter forming a plurality of semiconductor stacks by separating the first light reflection layer, the active layer, and the second light reflection layer into a plurality of pieces by etching, with the first buffer layer serving as an etching stop layer.

A method of manufacturing a second light-emitting device according to one embodiment of the present disclosure includes: forming a second light reflection layer, an active layer, a first light reflection layer configured by an arsenic-based semiconductor layer including carbon as an impurity, a second buffer layer configured by an arsenic-based semiconductor layer including zinc or magnesium as an impurity, and a first buffer layer configured by a phosphorus-based semiconductor layer in this order by a crystal growth; and thereafter forming a light output face, with the first buffer layer serving as an etching stop layer.

In the light-emitting device according to one embodiment of the present disclosure, the method of manufacturing the first light-emitting device according to one embodiment, and the method of manufacturing the second light-emitting device according to one embodiment, the second buffer layer configured by the arsenic-based semiconductor layer including zinc or magnesium as the impurity is provided between the first light reflection layer that configures the semiconductor stack and is configured by the arsenic-based semiconductor layer including carbon as the impurity and the first buffer layer configured by the phosphorus-based semiconductor layer. This suppresses a deterioration of a surface state of a crystal growth face due to contacting of an ingredient of a carbon included as an impurity in the first light reflection layer with a phosphorus-based semiconductor.

### BRIEF DESCRIPTION OF THE DRAWINGS

FIG. 1 is a schematic cross-sectional diagram illustrating an example of a configuration of a semiconductor laser according to a first embodiment of the present disclosure.

FIG. 2A is a schematic cross-sectional diagram illustrating an example of a method of manufacturing the semiconductor laser illustrated in FIG. 1.

FIG. 2B is a schematic cross-sectional diagram illustrating a process step following FIG. 2A.

FIG. 2C is a schematic cross-sectional diagram illustrating a process step following FIG. 2B.

FIG. 2D is a schematic cross-sectional diagram illustrating a process step following FIG. 2C.

FIG. 3 is a schematic cross-sectional diagram illustrating an example of a configuration of a semiconductor laser according to a second embodiment of the present disclosure.

FIG. 4A is a schematic cross-sectional diagram illustrating an example of a method of manufacturing the semiconductor laser illustrated in FIG. 3.

FIG. 4B is a schematic cross-sectional diagram illustrating a process step following FIG. 4A.

FIG. 4C is a schematic cross-sectional diagram illustrating a process step following FIG. 4B.

FIG. 4D is a schematic cross-sectional diagram illustrating a process step following FIG. 4C.

FIG. 5 is a block diagram illustrating an example of a schematic configuration of a distance measuring apparatus that uses an illumination device having the semiconductor laser illustrated in FIG. 1 or the like.

### MODES FOR CARRYING OUT THE INVENTION

The following describes embodiments of the present disclosure in detail with reference to the drawings. The following descriptions are one specific example of the present disclosure, and the present disclosure is not limited to the following embodiments. In addition, the present disclosure is not limited to arrangement, dimensions, dimensional ratios, and the like of the constituent elements illustrated in the drawings. It is to be noted that the description is given in the following order.

1. First Embodiment (an example of a semiconductor laser of a backside output type that has a second buffer layer configured by an arsenic-based semiconductor doped with Zn or Mg between a first reflection layer configured by a C-doped arsenic-based semiconductor and a first buffer layer configured by a phosphorus-based semiconductor layer)

1-1. Configuration of Semiconductor Laser

1-2. Method of Manufacturing Semiconductor Laser

1-3. Workings and Effects

2. Second Embodiment (an example of a semiconductor laser of a frontside output type that has a second buffer layer configured by an arsenic-based semiconductor doped with Zn or Mg between a first reflection layer configured by a C-doped arsenic-based semiconductor and a first buffer layer configured by a phosphorus-based semiconductor layer)
3. Application Example (an example of a distance measuring apparatus)

### 1. First Embodiment

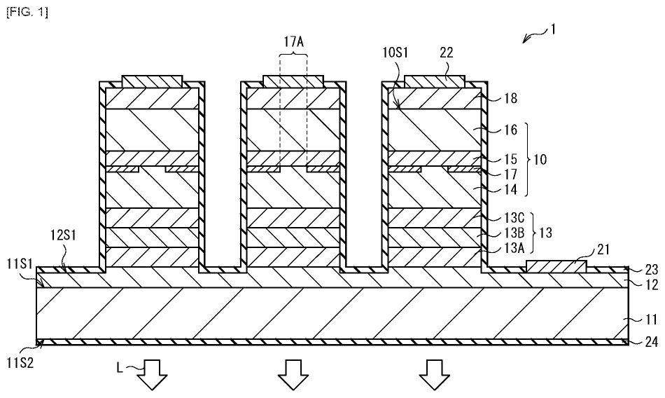

FIG. 1 schematically illustrates an example of a cross-sectional configuration of a light-emitting device (a semiconductor laser 1) according to a first embodiment of the present disclosure. The semiconductor laser 1 is, for example, a vertical resonator surface light-emission laser (Vertical Cavity Surface Emitting LASER: VCSEL) of a backside output type, and for example, a plurality of VCSELs is integrated in arrays as a plurality of light-emission regions.

(1-1. Configuration of Semiconductor Laser)

The semiconductor laser 1 has a plurality of semiconductor stacks 10 on a first face (a surface (a face 11S1)) of a substrate 11, for example. The semiconductor stack 10 has, for example, a columnar shape (a mesa shape), and, for example, a first light reflection layer 14, an active layer 15, and a second light reflection layer 16 are stacked in this order. A current confining layer 17 that forms a current injection region 17A is provided between the first light reflection layer 14 and the active layer 15. The semiconductor stack 10 corresponds to one specific example of a “semiconductor stack” of the present disclosure. Between the semiconductor stack 10 and the substrate 11, a first contact layer 12 and a buffer layer 13 are stacked in order from the substrate side, and the buffer layer 13 has a multilayer structure in which, for example, a first layer 13A, a second layer 13B, and a third layer 13C are stacked in this order from the first contact layer 12 side, and forms the mesa shape together with the semiconductor stack 10. The first contact layer 12 extends over the substrate 11 as a common layer for the plurality of semiconductor stacks 10. On the first contact layer 12, a first electrode 21 is provided as a common electrode of each of the semiconductor stacks 10. Upper faces (faces 10S1) of the respective semiconductor stacks 10 are each formed with a second contact layer 18 and a second electrode 22 in this order. Further, an upper face (a face 12S1) of the first contact layer 12 excluding the first electrode 21 and the second electrode 22, an upper face of the second contact layer 18, and side faces of the second contact layer 18, the semiconductor stack 10, and the buffer layer 13 are covered with an insulation film 23, and a second face (a back face (a face 11S2)) of the substrate 11 is covered with an insulation film 24.

Hereinafter, a configuration, a material, and the like of each part of the semiconductor laser 1 will be described in detail.

The substrate 11 is a supporting substrate for integrating the plurality of semiconductor stacks 10. As in the present embodiment, in the semiconductor laser 1 of the backside output type, it is preferable to use, as the substrate 11, a semi-insulating substrate which does not include an impurity, for example, and is configured by a GaAs-based semiconductor, for example. Besides, the substrate 11 may be any substrate having a low carrier concentration and reduced absorption of laser light, and for example, it is possible to use a substrate having a carrier concentration of 5×10¹⁷ cm⁻³ or less in a p-type or n-type carrier concentration.

The first contact layer 12 is configured by a GaAs-based semiconductor, for example. The first contact layer 12 is for electrically coupling the first electrode 21 and the first light reflection layer 14 of each semiconductor stack 10. The first contact layer 12 is configured by p-type GaAs and includes, for example, carbon (C) as an impurity. The first contact layer 12 corresponds to one specific example of a “first contact layer” of the present disclosure.

As described above, the buffer layer 13 has the multilayer structure in which the first layer 13A, the second layer 13B, and the third layer 13C are stacked in this order from the first contact layer 12 side. The first layer 13A is configured by, for example, an arsenic-based semiconductor layer including zinc (Zn) or magnesium (Mg) as an impurity. The second layer 13B is configured by, for example, a phosphorus-based semiconductor layer including zinc (Zn) or magnesium (Mg) as an impurity. As with the first layer 13A, the third layer 13C is configured by, for example, an arsenic-based semiconductor layer including zinc (Zn) or magnesium (Mg) as an impurity.

The arsenic-based semiconductor layer is a layer that includes a compound semiconductor including at least arsenic (As), and examples of which includes a GaAs layer, an AlGaAs layer, and an AlAs layer. The first layer 13A and the third layer 13C correspond to one specific example of a “second buffer layer” of the present disclosure, and can be formed as a monolayer film or a multilayer film configured by any one layer or two or more layers of the above semiconductor layer. A film thickness in a stacking direction of the first layer 13A and the third layer 13C (hereinafter referred to simply as a thickness) is, for example, 5 nm or greater and 100 nm or less.

The phosphorus-based semiconductor layer is a layer that includes a compound semiconductor including at least phosphorus (P), and examples of which includes a GaInP layer, an AlGaInP layer, and an AlInP layer. The second layer 13B corresponds to one specific example of a “first buffer layer” of the present disclosure, and can be formed as a monolayer film or a multilayer film configured by any one or two or more layers of the above semiconductor layer. A thickness of the second layer 13B is, for example, 50 nm or greater and 300 nm or less.

The first light reflection layer 14 is disposed between the buffer layer 13 and the current confining layer 17, and faces the second light reflection layer 16 with the active layer 15 and the current confining layer 17 therebetween. The first light reflection layer 14 resonates light generated at the active layer 15 between the first light reflection layer 14 and the second light reflection layer 16. The first light reflection layer 14 corresponds to one specific example of a “first light reflection layer” of the present disclosure.

The first light reflection layer 14 is a DBR (Distributed Bragg Reflector) layer in which a low refractive index layer (not illustrated) and a high refractive index layer (not illustrated) are alternately stacked. The low refractive index layer is configured by, for example, p-type Alₓ₁Ga₁₋ₓ₁As (0<x1≤1) having an optical thickness of λ×1/4n, and the high refractive index layer is configured by, for example, p-type Alₓ₂Ga₁₋ₓ₂As (0≤x2<x1) having an optical thickness of λ×1/4n. λ is an oscillation wavelength of laser light emitted from each light-emission region, and n is a refractive index. The first light reflection layer 14 includes, for example, carbon (C) as an impurity.

The active layer 15 is provided between the first light reflection layer 14 and the second light reflection layer 16. The active layer 15 is configured by, for example, an aluminum gallium arsenide (AlGaAs) based semiconductor material. In the active layer 15, holes and electrons injected from the first electrode 21 and the second electrode 22 are recombined to emit stimulated emission light. A region of the active layer 15 facing the current injection region 17A serves as a light-emission region. For example, it is possible to use undoped Alₓ₃Ga₁₋ₓ₃As (0<x3≤0.45) for the active layer 15. The active layer 15 may have, for example, a multi-quantum well (MQW: Multi Quantum Well) structure of GaAs and AlGaAs. Besides, a multi-quantum well structure of indium-gallium-arsenide (InGaAs) and AlGaAs may configure the active layer 15. The active layer 15 corresponds to one specific example of an “active layer” of the present disclosure.

The second light reflection layer 16 is a DBR layer disposed between the active layer 15 and the second contact layer 18. The second light reflection layer 16 faces the first light reflection layer 14 with the active layer 15 and the current confining layer 17 therebetween. The second light reflection layer 16 corresponds to one specific example of a “second light reflection layer” of the present disclosure.

The second light reflection layer 16 has a stack structure in which a low refractive index layer and a high refractive index layer are alternately stacked. The low refractive index layer is, for example, n-type Alₓ₄Ga₁₋ₓ₄As (0<x4≤1) having an optical film thickness of λ/4n. The high refractive index layer is, for example, n-type Alₓ₅Ga₁₋ₓ₅As (0≤x5<x4) having an optical film thickness of λ/4n. The second light reflection layer 16 includes, for example, silicon (Si) as an impurity.

The current confining layer 17 is provided between the first light reflection layer 14 and the active layer 15, and is, for example, so annularly formed as to have a predetermined width from an outer circumference side to an inner side of the semiconductor stack 10 having the mesa shape. In other words, the current confining layer 17 is provided between the first light reflection layer 14 and the active layer 15, and has an opening of a predetermined width at a middle part thereof. The opening serves as the current injection region 17A. The current confining layer 17 is configured by, for example, p-type AlGaAs. Specifically, the current confining layer 17 is configured by Al_{0.85}Ga_{0.15}As to AlAs, which are oxidized to form an aluminum oxide (AlOₓ) layer, thereby confining a current. In the semiconductor laser 1, by providing the current confining layer 17, the current injected from the first electrode 21 to the active layer 15 is narrowed and a current injection efficiency is increased.

The second contact layer 18 is configured by, for example, GaAs-based semiconductor, which has electric conductivity. The second contact layer 18 is configured by, for example, n-type GaAs, and includes, for example, silicon (Si) as an impurity. The second contact layer 18 corresponds to one specific example of a “second contact layer” of the present disclosure.

The first electrode 21 is provided on the first contact layer 12, and is configured by, for example, a multilayer film of titanium (Ti)/platinum (Pt)/gold (Au).

The second electrode 22 is provided above the semiconductor stack 10, specifically on the second contact layer 18, and is configured by, for example, a multilayer film of gold-germanium (Au—Ge)/nickel (Ni)/gold (Au).

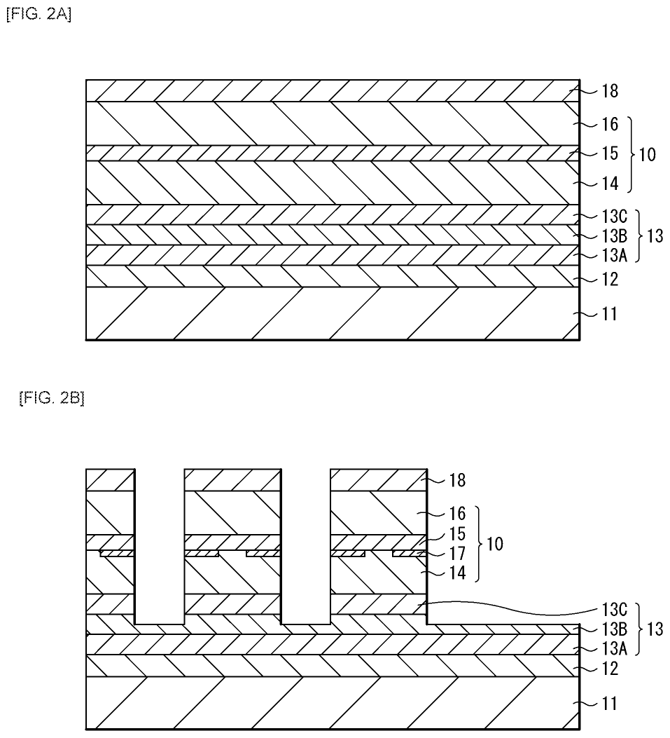

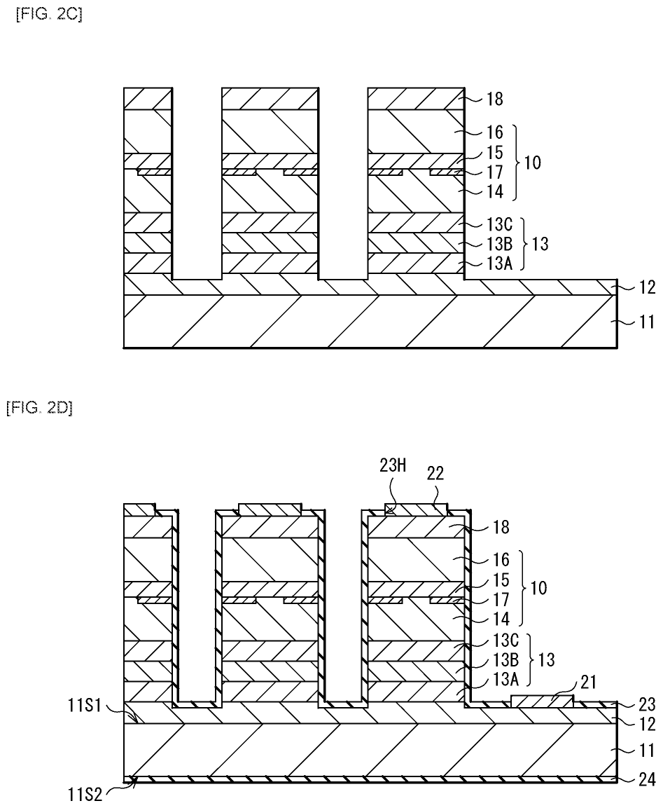

The insulation film 23 is formed, for example, continuously on an upper face of the second contact layer 18, side faces of the second contact layer 18, the semiconductor stack 10, and the buffer layer 13, and an upper face (a face 12S1) of the first contact layer 12. The insulation film 23 is configured by, for example, a monolayer film or a multilayer film of silicon nitride (SiN), silicon oxide (SiO₂), or the like. Predetermined positions, of the insulation film 23, at the upper face of each second contact layer 18 and the first contact layer 12 are each provided with an opening 23H (for example, see FIG. 2D), and the first electrode 21 or the second electrode 22 is embedded in each opening 23H.

The insulation film 24 is formed, for example, on an entire surface of a back face (a face 11S2) of the substrate 11. As with the insulation film 24, the insulation film 24 is configured by, for example, a monolayer film or a multilayer film of silicon nitride (SiN), silicon oxide (SiO₂), or the like.

The semiconductor laser 1 of the present embodiment is a semiconductor laser having a so-called anode common structure in which the plurality of semiconductor stacks 10 provided on the substrate 11 and the first electrode 21 are electrically coupled to each other by the first contact layer 12 configured by, for example, p-type GaAs.

In the semiconductor laser 1, when a predetermined voltage is applied to the first electrode 21 and the second electrode 22, a voltage is applied from the first electrode 21 and the second electrode 22 to the semiconductor stack 10. As a result, electrons are injected into the active layer 15 from the first electrode 21 and holes are injected into the active layer 15 from the second electrode 22, and light is generated by the recombination of the electrons and the holes. The light resonates between the first light reflection layer 14 and the second light reflection layer 16 and is amplified, and laser light L is outputted from the back face (the face 1152) of the substrate 11.

(1-2. Method of Manufacturing Semiconductor Laser)

Next, referring to FIGS. 2A to 2D, a method of manufacturing the semiconductor laser 1 will be described.

First, as illustrated in FIG. 2A, each compound semiconductor layer configuring the first contact layer 12, the buffer layer 13, the first light reflection layer 14, the active layer 15, the second light reflection layer 16, and the second contact layer 18 is formed on the substrate 11 in this order by an epitaxial crystal growth method such as a metal organic chemical vapor deposition (Metal Organic Chemical Vapor Deposition: MOCVD) method to fabricate an epiwafer. At this time, a methyl-based organic metal compound such as trimethylaluminum (TMAl), trimethylgallium (TMGa), trimethylindium (TMIn) or the like and an arsine (AsH₃) gas are used as ingredients of the arsenic-based semiconductor including the GaAs-based semiconductor, disilane (Si₂H₆), for example, is used as an ingredient of a doner impurity, and carbon tetrabromide (CBr₄), for example, is used as an ingredient of an acceptor impurity. As ingredients of the phosphorus-based semiconductor (e.g., AlGaInP), for example, a methyl-based organic metal compound such as trimethylaluminum (TMAl), trimethylgallium (TMGa), trimethylindium (TMIn) or the like and a phosphine (PH₃) gas are used, and disilane (Si₂H₆), for example, is used as an ingredient of a doner impurity, and dimethylzinc (DMZn) or cyclopentadienylmagnesium (Cp₂Mg), for example, is used as an ingredient of an acceptor impurity.

Subsequently, as illustrated in FIG. 2B, a resist film (not illustrated) of a predetermined pattern is formed on the second contact layer 18, following which the second contact layer 18, the second light reflection layer 16, the active layer 15, and the first light reflection layer 14 are etched using the resist film as a mask to form a columnar mesa structure (the semiconductor stack 10). At this time, it is preferable to use, for example, RIE (Reactive Ion Etching) that uses a Cl-based gas. In the etching of the second contact layer 18, the second light reflection layer 16, the active layer 15, and the first light reflection layer 14, the second layer 13B of the buffer layer 13 functions as an etching stop layer. Thus, an etching depth within a wafer plane becomes constant. Thereafter, a high-temperature process is performed in a water-vapor atmosphere to oxidize, for example, an AlGaAs layer having a high-aluminum (Al) composition which has been stacked in advance during the epitaxial growth and thereby to form an oxidation layer (the current confining layer 17) that confines the current.

Next, as illustrated in FIG. 2C, the second layer 13B and the first layer 13A of the buffer layer 13 are removed by etching to expose the first contact layer 12.

Subsequently, as illustrated in FIG. 2D, the insulation film 24 is formed from the insulation film 23 that continues from the upper face of the second contact layer 18 to a region on the first contact layer 12 and on the back face (the face 11S2) of the substrate 11, following which the first electrode 21 and the second electrode 22 are respectively formed on the first contact layer 12 and the second contact layer 18. The insulation films 23 and 24 are formed by, for example, a chemical vapor deposition (CVD: Chemical Vapor Deposition) method or an atomic layer deposition (ALD: Atomic Layer Deposition) method. The insulation film 23 is so formed as to cover the entire upper face (the face 12S1) of the first contact layer 12 exposed by etching from the upper face of the second contact layer 18, following which a resist film (not illustrated) of a predetermined pattern is formed on the insulation film 23, and etching such as RIE is performed to form the opening 23H at a predetermined position. Thereafter, the first electrode 21 and the second electrode 22 are respectively patterned on the first contact layer 12 and on the upper face of the second contact layer 18 using, for example, a lift-off method that uses the resist pattern. Thus, the semiconductor laser 1 illustrated in FIG. 1 is completed.

(1-3. Workings and Effects)

In the semiconductor laser 1 of the present embodiment, the third layer 13C configured by the arsenic-based semiconductor layer including zinc (Zn) or magnesium (Mg) as the impurity is provided between the first light reflection layer 14 configured by the arsenic-based semiconductor layer including carbon (C) as the impurity and the second layer 13B configured by the phosphorus-based semiconductor layer configuring the buffer layer 13. This suppresses a deterioration in a surface state of a crystal growth face due to contacting of an acceptor impurity (e.g., carbon tetrabromide (CBr₄)) used as an ingredient of carbon (C) included in the first light reflection layer 14 with the phosphorus-based semiconductor configuring the second layer 13B. This will be described below.

As described previously, a surface light-emission laser has been developed in which a p-type InGaP layer doped with zinc (Zn) as an impurity is formed between p-type DBR and an ohmic contact layer configured by p-type GaAs, and in which the p-type InGaP layer laser is used as an etching stop layer to stabilize laser oscillation.

In the surface light-emission laser describe above, the p-type DBR and the ohmic contact layer configured by the p-type GaAs are each doped with carbon (C) as an impurity. In a crystal growth of a semiconductor laser including the surface light-emission laser, a MOCVD method is generally used, but upon doping carbon (C) in the MOCVD method, carbon tetrabromide (CBr₄), bromine chloride (BrCl₃), or the like is used as an ingredient. For example, in a case where carbon tetrabromide (CBr₄) is used, bromine (Br) is generated by thermal decomposition, for example, during a crystal growth of the p-type DBR. A portion of bromine (Br) generated remains in a reactor due to a memory effect. The bromine (Br) remaining in the reactor reacts easily with a phosphorus-based semiconductor to be brought into crystal growth next, that is, with the InGaP layer described above, and may cause a deterioration of a surface state (e.g., flatness) of the InGaP layer, generation of a crystalline defect, dust, or the like caused by a reactant on a surface of the InGaP layer, which can cause a deterioration of a device characteristic and a decrease in a manufacturing yield.

In contrast, in the present embodiment, the third layer 13C configured by the arsenic-based semiconductor layer including zinc (Zn) or magnesium (Mg) as the impurity is provided between the first light reflection layer 14 configured by the arsenic-based semiconductor layer including carbon (C) as the impurity and the second layer 13B configured by the phosphorus-based semiconductor layer. Thus, the deterioration of the surface state of the crystal growth face due to contacting of a C-doped material such as carbon tetrabromide (CBr₄) with the second layer 13B configured by the phosphorus-based semiconductor is suppressed. Specifically, it is possible to prevent an etching reaction with the phosphorus-based semiconductor layer caused by the C-doped material and to prevent generation of a defective pit and a deterioration of surface morphology in a crystal growth face.

As described above, in the semiconductor laser 1 of the present embodiment, because the third layer 13C configured by the arsenic-based semiconductor layer including zinc (Zn) or magnesium (Mg) as the impurity is provided between the first light reflection layer 14 configured by the arsenic-based semiconductor layer including carbon (C) as the impurity and the second layer 13B configured by the phosphorus-based semiconductor layer, the deterioration of the surface state of the crystal growth face due to the contacting of the C-doped material with the phosphorus-based semiconductor is suppressed, and an epi-layer having excellent flatness is formed on and above the phosphorus-based semiconductor layer (the second layer 13B). Accordingly, it is possible to improve a device characteristic and a manufacturing yield of the surface light-emission laser.

Further, in the present embodiment, because the first contact layer 12 is configured by a GaAs-based semiconductor including carbon (C) as an impurity, the first layer 13A configured by the arsenic-based semiconductor layer including zinc (Zn) or magnesium (Mg) is also provided between the first contact layer 12 and the second layer 13B configured by the phosphorus-based semiconductor layer. Thus, it is possible to suppress the contacting of a C-doped material such as carbon tetrabromide (CBr₄) used upon forming the first contact layer 12 with the second layer 13B configured by the phosphorus-based semiconductor and to form the first contact layer 12 and the second layer 13B having excellent flatness.

Hereinafter, a second embodiment and an application example of the present disclosure will be described. In the following, the same component as those of the above first embodiment will be denoted by the same reference numerals, and descriptions thereof will be omitted as appropriate.

### 2. Second Embodiment

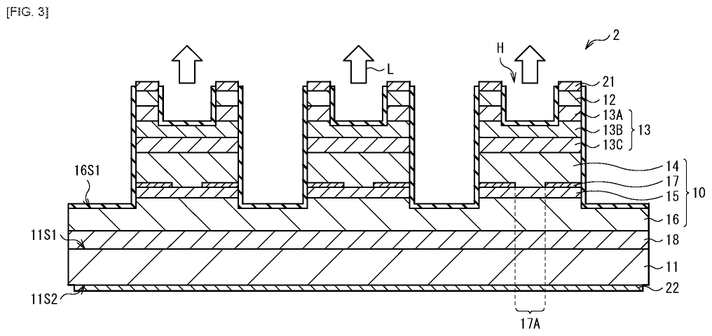

FIG. 3 schematically illustrates an example of a cross-sectional configuration of a light-emitting device (a semiconductor laser 2) according to the second embodiment of the present disclosure. The semiconductor laser 2 is, for example, a vertical resonator surface light-emission laser (Vertical Cavity Surface Emitting LASER: VCSEL) of a frontside output type, and for example, a plurality of VCSELs is integrated in arrays as a plurality of light-emission regions.

The semiconductor laser 2 has the plurality of semiconductor stacks 10 on the first face (the surface (the face 11S 1)) of the substrate 11, for example. A portion of the plurality of semiconductor stacks 10 has a columnar shape (a mesa shape). In the semiconductor stack 10 of the present embodiment, for example, the second light reflection layer 16, the active layer 15, and the first light reflection layer 14 are stacked in this order, and the current confining layer 17 that forms the current injection region 17A is provided between the first light reflection layer 14 and the active layer 15. A second contact layer 18 is provided between the semiconductor stack 10 and the substrate 11, and the buffer layer 13 and the first contact layer 12 are stacked in this order on an upper face of each semiconductor stack 10. In the buffer layer 13, for example, the third layer 13C, the second layer 13B, and the first layer 13A are stacked in this order from the semiconductor stack 10 side. In the present embodiment, the second contact layer 18 and a portion of the second light reflection layer 16 extend over the substrate 11 as a common layer for the plurality of semiconductor stacks 10. In addition, an opening H that serves as a light output face is formed on the first contact layer 12 and the first layer 13A configuring the buffer layer 13 above the current injection region 17A, and the first electrode 21 is provided on the first contact layer 12 positioned around the opening H. The second electrode 22 is provided on the back face (the face 1152) of the substrate 11 as a common electrode for the plurality of semiconductor stacks 10. Further, a side face and a bottom face of the opening H, side faces of the first contact layer 12, the buffer layer 13, the first light reflection layer 14, the current confining layer 17, the active layer 15, a portion of a side face of the second light reflection layer 16, and an upper face (a face 16S1) of the second light reflection layer 16 common to each semiconductor stack 10 are covered with 1 insulation film 23.

It is possible to manufacture the semiconductor laser 2, for example, as follows.

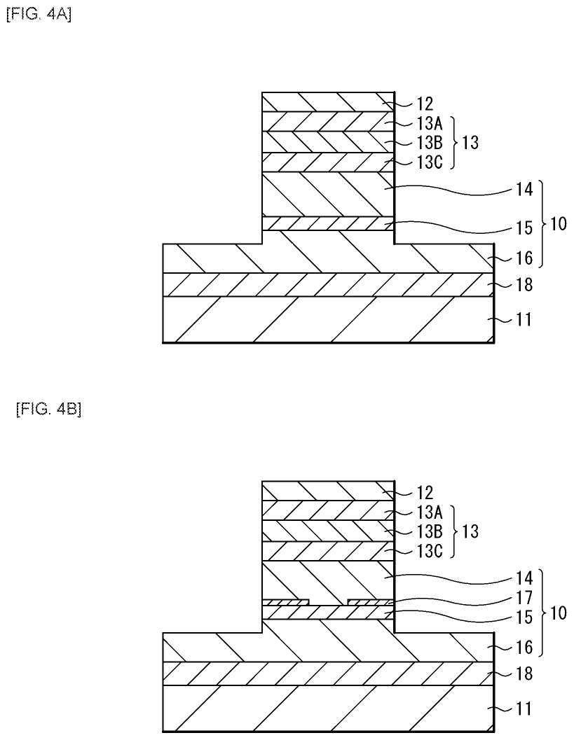

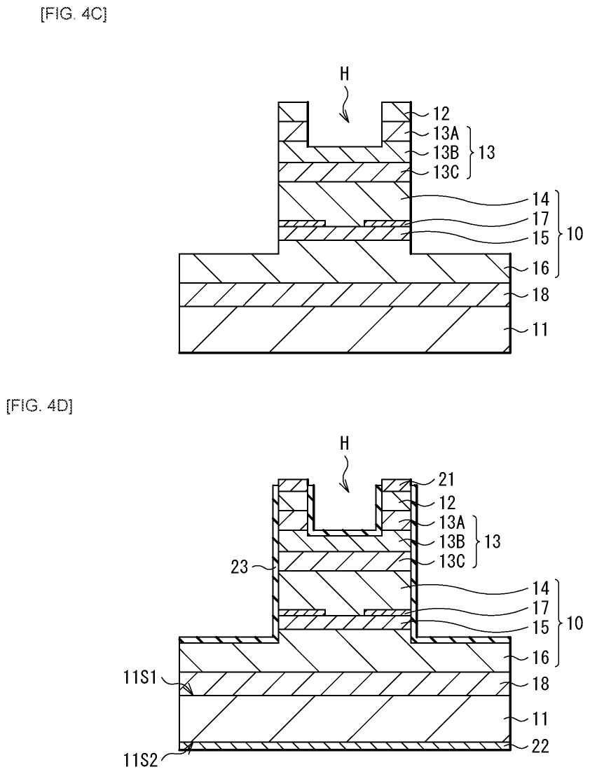

First, as illustrated in FIG. 4A, each compound semiconductor layer configuring the second contact layer 18, the second light reflection layer 16, the active layer 15, the first light reflection layer 14, the buffer layer 13, and the first contact layer 12 is formed on the substrate 11 in this order by an epitaxial crystal growth method such as a MOCVD method, for example, to fabricate an epiwafer, following which etching is performed to the second light reflection layer 16 to form a columnar mesa structure (the semiconductor stack 10).

Thereafter, as illustrated in FIG. 4B, a high-temperature process is performed in a water-vapor atmosphere to oxidize, for example, an AlGaAs layer having a high-aluminum (Al) composition which has been stacked in advance during the epitaxial growth and thereby to form an oxidation layer (the current confining layer 17) that confines the current.

Next, as illustrated in FIG. 4C, using the second layer 13B as an etching stop layer, the first contact layer 12 and the first layer 13A above the current injection region 17A are selectively removed by, for example, wet etching to form the opening H whose bottom face serves as the light output face.

Subsequently, as illustrated in FIG. 4D, the insulation film 23 that continues from the side face and the bottom face of the opening H and the upper face of the first contact layer 12 around the opening H to the upper face (the face 16S1) of the second light reflection layer 16 is formed, following which the first electrode 21 and the second electrode 22 are respectively formed on the upper face of the first contact layer 12 and the back face (the face 11S2) of the substrate 11. The insulation film 23 is so formed by, for example, a CVD method or an ALD method as to cover from the side face and the bottom face of the opening H and the upper face of the first contact layer 12 around the opening H to the upper face (the face 16S1) of the second light reflection layer 16 as a whole, following which a resist film (not illustrated) of a predetermined pattern is patterned, and etching such as RIE is performed to form an opening on the first contact layer 12. Thereafter, the first electrode 21 is patterned on the first contact layer 12 using, for example, a lift-off method that uses the resist pattern. Thus, the semiconductor laser 2 illustrated in FIG. 3 is completed.

As described above, in the semiconductor laser 2 of the present embodiment, the third layer 13C configured by the arsenic-based semiconductor layer including zinc (Zn) or magnesium (Mg) as the impurity is provided between the first light reflection layer 14 configured by the arsenic-based semiconductor layer including carbon (C) as the impurity and in which the second contact layer 18, the second light reflection layer 16, the active layer 15, the first light reflection layer 14, the buffer layer 13, and the second layer 13B are stacked in this order from the substrate 11 side and the second layer 13B configured by the phosphorus-based semiconductor layer. In addition, the first layer 13A having the similar configuration to the third layer 13C is provided between the second layer 13B configured by the phosphorus-based semiconductor layer and the first contact layer 12 configured by the arsenic-based semiconductor layer including carbon (C) as the impurity. In the semiconductor laser 2 of the frontside output type having such a configuration as well, it is possible to achieve similar effects to the first embodiment described above. That is, it is possible to improve a device characteristic and a manufacturing yield of the surface light-emission laser.

It should be noted that, in the semiconductor laser 2 of the present embodiment, because the laser light L is outputted from a region above the semiconductor stack 10, the substrate 11 is not limited to a semi-insulating substrate referred to in the first embodiment described above, and a typical gallium arsenide (GaAs) substrate may be used. Besides, the substrate 11 may be configured by indium-phosphorus (InP), gallium nitride (GaN), silicon (Si), silicon carbide (SiC), or the like by materials of a light-emitting device, a bonding process of dissimilar-substrates, or the like.

### 3. Application Example

It is possible to apply the present technology to various electronic apparatuses that include the semiconductor laser. For example, it is possible to apply the present technology to a light source provided in a portable electronic apparatus such as a smartphone, a light source of various sensing devices that detect a shape, operation, or the like, etc.

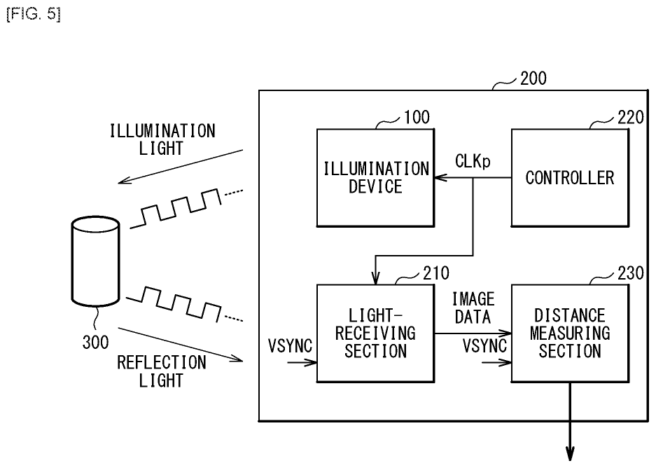

FIG. 5 is a block diagram illustrating a schematic configuration of a distance measuring apparatus (a distance measuring apparatus 200) that uses an illumination device 100 having the above-described semiconductor laser 1. The distance measuring apparatus 200 measures a distance by a ToF method. The distance measuring apparatus 200 includes, for example, an illumination device 100, a light-receiving section 210, a controller 220, and a distance measuring section 230.

The illumination device 100 includes, for example, the semiconductor laser 1 illustrated in FIG. 1 or the like as a light source. In the illumination device 100, for example, illumination light is generated in synchronization with a light-emission control signal CLKp of a rectangular wave. Further, the light-emission control signal CLKp is not limited to the rectangular wave as long as it is a periodic signal. For example, the light-emission control signal CLKp may be a sine wave.

The light-receiving section 210 receives reflection light reflected from an illumination target object 300, and detects a light-reception amount in a period every time the period of the vertical synchronization signal VSYNC elapses. For example, 60 hertz (Hz) periodic signal is used as the vertical synchronization signal VSYNC. In addition, a plurality of pixel circuits is arranged in a two-dimensional grid pattern in the light-receiving section 210. The light-receiving section 210 supplies image data (a frame) corresponding to a light-reception amount of the pixel circuit to the distance measuring section 230. A frequency of the vertical synchronization signal VSYNC is not limited to 60 hertz (Hz), and may be 30 hertz (Hz) or 120 hertz (Hz).

The controller 220 controls the illumination device 100. The controller 220 generates and supplies a light-emission control signal CLKp to the illumination device 100 and the light-receiving section 210. A frequency of the light-emission control signal CLKp is, for example, 20 megahertz (MHz). It should be noted that the frequency of the light-emission control signal CLKp is not limited to 20 megahertz (MHz), and may be, for example, 5 megahertz (MHz).

The distance measuring section 230 measures a distance to the illumination target object 300 by the ToF method on the basis of image data. In the distance measuring section 230, the distance is measured for each pixel circuit, and a depth map indicating the distance to the object for each pixel in terms of a gradation value is generated. The depth map is used, for example, in an image process in which a blurring process of a degree corresponding to the distance is performed, an auto-focus (AF) process in which a focal point of a focus lens is determined in accordance with the distance, or the like.

Although the present technology has been described with reference to the first and the second embodiments and the application example, the present technology is not limited to the above-described embodiments and the like, and various modifications can be made. For example, a layer configuration of the semiconductor laser 1 or 2 described in the above first embodiment or the like is exemplary, and may further include another layer. Further, a material of each layer is also an example, and is not limited to those described above.

For example, in the above first embodiment or the like, an example has been described in which the first contact layer 12 includes carbon (C) as an impurity (a dopant), but the dopant of the first contact layer 12 is not limited to carbon (C). For example, the first contact layer 12 may include zinc (Zn) or the like as the dopant, similarly to the buffer layer 13. In such a case, the first layer 13A of the buffer layer 13 in contact with the first contact layer 12 may be omitted.

Further, in the above first embodiment, an example of the semiconductor laser (the semiconductor laser 1) of the backside output type having the anode common structure has been illustrated in which the first contact layer 12, the buffer layer 13, the first light reflection layer 14, the active layer 15, the second light reflection layer 16, and the second contact layer 18 are stacked in this order on the substrate 11, although it is not limited thereto. For example, as in the semiconductor laser 2 of the second embodiment, the semiconductor laser 1 may be configured as the semiconductor laser of the backside output type having a so-called cathode common structure in which the second contact layer 18, the second light reflection layer 16, the active layer 15, the first light reflection layer 14, the buffer layer 13, and the first contact layer 12 are stacked in this order from the substrate 11 side. Similarly, the semiconductor laser (the semiconductor laser 2) of the frontside output type described in the above second embodiment may also have a configuration in which the first contact layer 12, the buffer layer 13, the first light reflection layer 14, the active layer 15, the second light reflection layer 16, and the second contact layer 18 are stacked in order from the substrate 11 side.

It should be noted that the effects described herein are merely illustrative and not restrictive, and other effects may be obtained.

It should be noted that the present technology may be configured as below. According to the present technology of the following configurations, the second buffer layer configured by the arsenic-based semiconductor layer including zinc or magnesium as the impurity is provided between the first light reflection layer that configures the semiconductor stack and is configured by the arsenic-based semiconductor layer including carbon as the impurity and the first buffer layer configured by the phosphorus-based semiconductor layer. This suppresses a deterioration of a surface state of a crystal growth face due to contacting of an ingredient of a carbon included as an impurity in the first light reflection layer with a phosphorus-based semiconductor. Hence, it is possible to improve stability of a device characteristic and a manufacturing yield.

(1)

A light-emitting device including:

a semiconductor stack in which a first light reflection layer configured by an arsenic-based semiconductor layer including carbon as an impurity, an active layer, and a second light reflection layer are stacked;

a first buffer layer provided on the first light reflection layer side of the semiconductor stack, having one face that faces the semiconductor stack and another face that is on an opposite side of the one face, and configured by a phosphorus-based semiconductor layer; and

a second buffer layer provided at least between the first light reflection layer and the first buffer layer, and configured by an arsenic-based semiconductor layer including zinc or magnesium as an impurity.

(2)

The light-emitting device according to (1), in which the arsenic-based semiconductor layer is a monolayer film or a multilayer film configured by any one or two or more layers of an GaAs layer, an AlGaAs layer, and an AlAs layer.

(3)

The light-emitting device according to (1) or (2), in which the phosphorus-based semiconductor layer is a monolayer film or a multilayer film configured by any one or two or more layers of a GaInP layer, an AlGaInP layer, and an AlInP layer.

(4)

The light-emitting device according to any one of (1) to (3), further including a first contact layer provided on the other face side of the first buffer layer.

(5)

The light-emitting device according to (4), in which

the first contact layer is configured by an arsenic-based semiconductor layer including carbon as an impurity, and

the second buffer layer is provided on both the one face and the other face of the first buffer layer.

(6)

The light-emitting device according to any one of (1) to (5), further including a substrate on which the semiconductor stack is stacked, in which

the semiconductor stack is stacked in order of the first light reflection layer, the active layer, and the second light reflection layer from the substrate side.

(7)

The light-emitting device according to any one of (1) to (5), further including a substrate on which the semiconductor stack is stacked, in which

the semiconductor stack is stacked in order of the second light reflection layer, the active layer, and the first light reflection layer from the substrate side.

(8)

The light-emitting device according to any one of (1) to (7), in which the semiconductor stack further includes a current confining layer having a current injection region between the first light reflection layer and the active layer.

(9)

The light-emitting device according to any one of (1) to (8), further including a second contact layer provided on the second light reflection layer side of the semiconductor stack.

(10)

The light-emitting device according to any one of (1) to (9), further including a first electrode and a second electrode that are configured to apply a predetermined voltage to the semiconductor stack.

(11)

The light-emitting device according to any one of (1) to (5), further including a substrate on which the semiconductor stack is stacked, in which

the semiconductor stack outputs laser light on the substrate side.

(12)

The light-emitting device according to (11), in which the substrate includes a semi-insulating substrate having a p-type or n-type carrier concentration of 5×10¹⁷ cm⁻³ or less.

(13)

The light-emitting device according to any one of (1) to (5), (11), and (12), in which the semiconductor stack outputs laser light above the semiconductor stack.

(14)

A method of manufacturing a light-emitting device, the method including:

forming a first buffer layer configured by a phosphorus-based semiconductor layer, a second buffer layer configured by an arsenic-based semiconductor layer including zinc or magnesium as an impurity, a first light reflection layer configured by an arsenic-based semiconductor layer including carbon as an impurity, an active layer, and a second light reflection layer in this order by a crystal growth; and

thereafter forming a plurality of semiconductor stacks by separating the first light reflection layer, the active layer, and the second light reflection layer into a plurality of pieces by etching, with the first buffer layer serving as an etching stop layer.

(15)

The method of manufacturing the light-emitting device according to (14), further including:

forming, prior to the crystal growth of the first buffer layer and the second buffer layer, a first contact layer below the first buffer layer; and

exposing, after the etching, the first contact layer by further etching the first buffer layer.

(16)

The method of manufacturing the light-emitting device according to (14) or (15), in which the first buffer layer, the second buffer layer, the first light reflection layer, the active layer, and the second light reflection layer are continuously formed by a metal organic chemical vapor deposition method.

(17)

A method of manufacturing a light-emitting device, the method including:

forming a second light reflection layer, an active layer, a first light reflection layer configured by an arsenic-based semiconductor layer including carbon as an impurity, a second buffer layer configured by an arsenic-based semiconductor layer including zinc or magnesium as an impurity, and a first buffer layer configured by a phosphorus-based semiconductor layer in this order by a crystal growth; and

thereafter forming a light output face, with the first buffer layer serving as an etching stop layer.

The present application claims the benefit of Japanese Priority Patent Application JP2020-025190 filed with the Japan Patent Office on Feb. 18, 2020, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light-emitting device comprising:
a semiconductor stack in which a first light reflection layer configured by an arsenic-based semiconductor layer including carbon as an impurity, an active layer, and a second light reflection layer are stacked;
a first buffer layer provided on the first light reflection layer side of the semiconductor stack, having one face that faces the semiconductor stack and another face that is on an opposite side of the one face, and configured by a phosphorus-based semiconductor layer; and
a second buffer layer provided at least between the first light reflection layer and the first buffer layer, and configured by an arsenic-based semiconductor layer including zinc or magnesium as an impurity.

2. The light-emitting device according to claim 1, wherein the arsenic-based semiconductor layer is a monolayer film or a multilayer film configured by any one or two or more layers of an GaAs layer, an AlGaAs layer, and an AlAs layer.

3. The light-emitting device according to claim 1, wherein the phosphorus-based semiconductor layer is a monolayer film or a multilayer film configured by any one or two or more layers of a GaInP layer, an AlGaInP layer, and an AlInP layer.

4. The light-emitting device according to claim 1, further comprising a first contact layer provided on the other face side of the first buffer layer.

5. The light-emitting device according to claim 4, wherein
the first contact layer is configured by an arsenic-based semiconductor layer including carbon as an impurity, and
the second buffer layer is provided on both the one face and the other face of the first buffer layer.

6. The light-emitting device according to claim 1, further comprising a substrate on which the semiconductor stack is stacked, wherein
the semiconductor stack is stacked in order of the first light reflection layer, the active layer, and the second light reflection layer from the substrate side.

7. The light-emitting device according to claim 1, further comprising a substrate on which the semiconductor stack is stacked, wherein
the semiconductor stack is stacked in order of the second light reflection layer, the active layer, and the first light reflection layer from the substrate side.

8. The light-emitting device according to claim 1, wherein the semiconductor stack further includes a current confining layer having a current injection region between the first light reflection layer and the active layer.

9. The light-emitting device according to claim 1, further comprising a second contact layer provided on the second light reflection layer side of the semiconductor stack.

10. The light-emitting device according to claim 1, further comprising a first electrode and a second electrode that are configured to apply a predetermined voltage to the semiconductor stack.

11. The light-emitting device according to claim 1, further comprising a substrate on which the semiconductor stack is stacked, wherein
the semiconductor stack outputs laser light on the substrate side.

12. The light-emitting device according to claim 11, wherein the substrate comprises a semi-insulating substrate having a p-type or n-type carrier concentration of 5×10¹⁷ cm⁻³ or less.

13. The light-emitting device according to claim 1, wherein the semiconductor stack outputs laser light above the semiconductor stack.

14. A method of manufacturing a light-emitting device, the method comprising:
forming a first buffer layer configured by a phosphorus-based semiconductor layer, a second buffer layer configured by an arsenic-based semiconductor layer including zinc or magnesium as an impurity, a first light reflection layer configured by an arsenic-based semiconductor layer including carbon as an impurity, an active layer, and a second light reflection layer in this order by a crystal growth; and
thereafter forming a plurality of semiconductor stacks by separating the first light reflection layer, the active layer, and the second light reflection layer into a plurality of pieces by etching, with the first buffer layer serving as an etching stop layer.

15. The method of manufacturing the light-emitting device according to claim 14, further comprising:
forming, prior to the crystal growth of the first buffer layer and the second buffer layer, a first contact layer below the first buffer layer; and
exposing, after the etching, the first contact layer by further etching the first buffer layer.

16. The method of manufacturing the light-emitting device according to claim 14, wherein the first buffer layer, the second buffer layer, the first light reflection layer, the active layer, and the second light reflection layer are continuously formed by a metal organic chemical vapor deposition method.

17. A method of manufacturing a light-emitting device, the method comprising:
forming a second light reflection layer, an active layer, a first light reflection layer configured by an arsenic-based semiconductor layer including carbon as an impurity, a second buffer layer configured by an arsenic-based semiconductor layer including zinc or magnesium as an impurity, and a first buffer layer configured by a phosphorus-based semiconductor layer in this order by a crystal growth; and
thereafter forming a light output face, with the first buffer layer serving as an etching stop layer.
